(19) United States
(12) Patent Application Publication
(10) Pub. No.: US 2010/0044082 A1
(43) Pub. Date: Feb. 25, 2010

(54) WIRING BOARD

(75) Inventors: Chun-Chien Chen, Taipei County (TW); Tsung-Yuan Chen, Taoyuan County (TW); Cheng-Po Yu, Taoyuan County (TW)

Correspondence Address: J C PATENTS, 4 VENTURE, SUITE 250, IRVINE, CA, 92618, US

(73) Assignee: UNIMICRON TECHNOLOGY CORP., Taoyuan (TW)

(21) Appl. No.: 12/260,306

(22) Filed: Oct. 29, 2008

(30) Foreign Application Priority Data
Aug. 20, 2008 (TW) 97131808

(51) Int. Cl. H05K 1/00

(52) U.S. Cl. 174/254

(57) ABSTRACT

A wiring board including two wiring layers and a flexible core layer is provided. The flexible core layer is disposed between the wiring layers, and the flexible core layer is an insulator. A flexure of the wiring board is between 0 degree and 170 degrees.

### CROSS-REFERENCE TO RELATED APPLICATION

This application claims the priority benefit of Taiwan application serial no. 97131808, filed on Aug. 20, 2008. The entirety of the above-mentioned patent application is hereby incorporated by reference herein and made a part of specification.

### BACKGROUND OF THE INVENTION

1. Field of the Invention

The present invention generally relates to a wiring board, in particular, to a rigid wiring board.

2. Description of Related Art

The wiring board is an important component required by many electronic devices. The wiring board may be assembled with a plurality of electronic components, for example, chips and passive components. The electronic components are, for example, a chip and a passive component. The electronic components are electrically connected to one another through the wiring board, such that signals are transmitted among the electronic components. In this manner, the electronic components may achieve their respective functions. Therefore, the wiring board is an important component of the electronic device.

However, the material of the conventional wiring board is relatively hard and poor flexible. Therefore, for example, during the wiring jet-printing process, the wiring board is easily broken under a pressure generated by a nozzle, such that the manufacturing process of the wiring board has a low yield and a high manufacturing cost. In addition, in order to maintain the strength of the wiring board, the wiring board must have a certain thickness, such that the manufacturing cost and the volume of the wiring board are increased. As known from the above descriptions that, currently, it has become a researching topic how to improve the product reliability of the wiring board.

### SUMMARY OF THE INVENTION

Accordingly, the present invention is directed to a wiring board, which has better product reliability.

The present invention is further directed to a wiring board, which has better flexibility.

As embodied and broadly described herein, the present invention provides a wiring board, which includes a first wiring layer, a second wiring layer, and a flexible core layer. The flexible core layer is disposed between the first wiring layer and the second wiring layer, in which the flexible core layer is an insulator, and a flexure of the wiring board is between 0 degree and 175 degrees.

In an embodiment of the present invention, a tensile strength of the wiring board is between 20 Mpa and 150 Mpa.

In an embodiment of the present invention, a tensile strength of the flexible core layer is between 20 Mpa and 150 Mpa.

In an embodiment of the present invention, a thickness of the wiring board is between 30 μm and 150 μm.

In an embodiment of the present invention, the first wiring layer and the second wiring layer are embedded in the flexible core layer.

In an embodiment of the present invention, the wiring board further includes a first flexible insulating layer, disposed on the first wiring layer, in which a flexure of the first flexible insulating layer is between 0 degree and 175 degrees.

In an embodiment of the present invention, a tensile strength of the first flexible insulating layer is between 20 Mpa and 150 Mpa.

In an embodiment of the present invention, the wiring board further includes a second flexible insulating layer, disposed on the second wiring layer, in which a flexure of the second flexible insulating layer is between 0 degree and 175 degrees.

In an embodiment of the present invention, a tensile strength of the second flexible insulating layer is between 20 Mpa and 150 Mpa.

The present invention further provides a wiring board, which includes a wiring substrate and a first flexible insulating layer. The wiring substrate has an upper surface and a lower surface opposite to the upper surface. The first flexible insulating layer is disposed on the upper surface, in which a flexure of the wiring board is between 0 degree and 175 degrees.

In an embodiment of the present invention, a tensile strength of the wiring board is between 20 Mpa and 150 Mpa.

In an embodiment of the present invention, a tensile strength of the first flexible insulating layer of the wiring board is between 20 Mpa and 150 Mpa.

In an embodiment of the present invention, a thickness of the wiring board is between 30 μm and 150 μm.

In an embodiment of the present invention, the wiring board further includes a second flexible insulating layer disposed on the lower surface, in which a flexure of the second flexible insulating layer is between 0 degree and 175 degrees.

In an embodiment of the present invention, a tensile strength of the second flexible insulating layer is between 20 Mpa and 150 Mpa.

In an embodiment of the present invention, the wiring substrate includes a first wiring layer, a second wiring layer, and an insulating layer. The insulating layer is disposed between the first wiring layer and the second wiring layer, in which the first flexible insulating layer partially covers the first wiring layer.

In the present invention, through the flexible core layer or the flexible insulating layers (for example, the first and second flexible insulating layers), the wiring board becomes relatively flexible, and the wiring board has a good flexibility. Therefore, the wiring board of the present invention can sustain the destruction of an external force and have good product reliability. Furthermore, the flexible core layer and the flexible insulating layers can sustain some physical destruction caused by certain processes, such that the present invention can reduce the situation that the wiring board is broken during the manufacturing process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a wiring board according to an embodiment of the present invention.

FIG. 2 is a schematic view depicted for demonstrating a flexure.

FIG. 3A is a schematic cross-sectional view of a wiring board according to another embodiment of the present invention.

FIG. 3B is a schematic cross-sectional view of the wiring board in FIG. 3A during a manufacturing process.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

FIG. 1 is a schematic cross-sectional view of a wiring board according to an embodiment of the present invention. Referring to FIG. 1, a wiring board 100 is a rigid wiring board instead of a flexible wiring board. The wiring board 100 includes a first wiring layer 110, a second wiring layer 120, and a flexible core layer 130, in which the flexible core layer 130 is disposed between the first wiring layer 110 and the second wiring layer 120, and a flexure of the wiring board 100 is between 0 degree and 175 degrees, in which the flexure represents a bending capability of the wiring board 100.

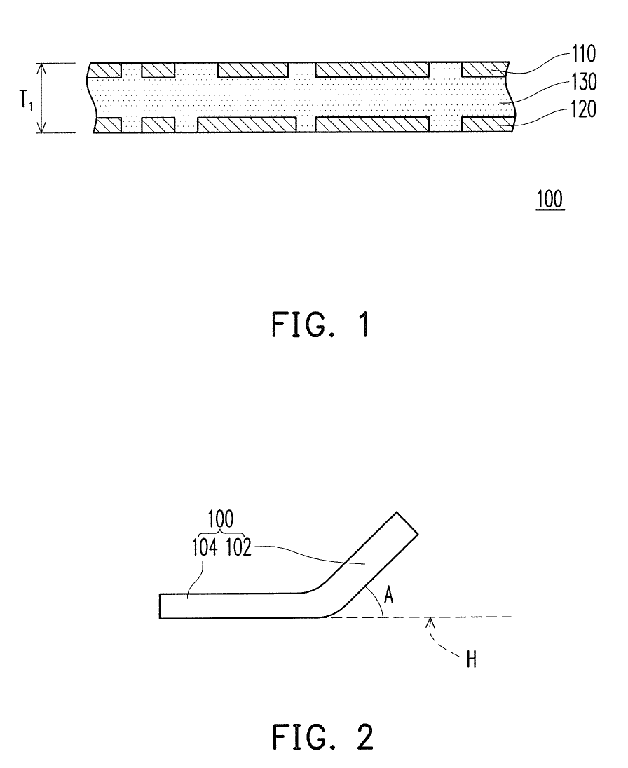

FIG. 2 is a schematic view depicted for demonstrating a flexure. Referring to FIG. 2, the flexure in the present invention refers to a largest bending angle of the wiring board 100. When the wiring board 100 is not bent, it is substantially a flat plate, and extended with a horizontal reference plane H, that is, the wiring board 100 lays flat on the horizontal reference plane H. When the wiring board 100 is bent, it may be differentiated into two board parts 102 and 104, in which the board part 104 still lays flat on the horizontal reference plane H, but an included angle A is formed between the board part 102 and the horizontal reference plane H.

When the included angle A exceeds N degrees, the wiring board 100 may be broken between the board parts 102 and 104, and in this case, the angle of N degrees is the flexure. That is to say, the flexure refers to the largest bending angle of the wiring board 100 under a condition that the wiring board 100 is not broken. Therefore, as for the wiring board, the higher the flexure is, the larger the largest bending angle is. It may be known that the flexure of the wiring board 100 between 0 degree and 175 degrees means that, when the wiring board 100 is bent, under the condition that the wiring board 100 is not broken, the largest angle between the board part 102 and the horizontal reference plane H is between 0 degree and 175 degrees.

Generally, the conventional flexible wiring board has a high flexure up to 180 degrees. In contrast, the conventional rigid wiring board has a low flexure lower than 90 degrees. Although the wiring board 100 of the present invention is a rigid wiring board, the flexure of the wiring board 100 is between 0 degree and 175 degrees. Therefore, as compared with the conventional rigid wiring board, the wiring board 100 of the present invention is relatively flexible and has a better flexibility, such that it is not easily broken under an external force. In addition, in this embodiment, a tensile strength of the wiring board 100 is between 20 Mpa and 150 Mpa. Therefore, as compared with the conventional rigid wiring board, the wiring board 100 can further sustain the destruction of an external force.

Referring to FIG. 1, there are many means for enabling the flexure of the wiring board 100 to reach between 0 degree and 175 degrees. In this embodiment, the flexible core layer 130 with a higher flexure or a higher tensile strength may be adopted. For example, the flexure of the flexible core layer 130 may be between 0 degree and 175 degrees, and the tensile strength of the flexible core layer 130 may be between 20 Mpa and 150 Mpa. In addition, the flexible core layer 130 may be made of a semi-flux material, and the semi-flux material may be resin doped with a filler material or pure resin without any filler material, in which the filler material is, for example, fiber.

The flexure of the flexible core layer 130 may be between 0 degree and 175 degrees, and the tensile strength may be between 20 Mpa and 150 Mpa. Therefore, during the manufacturing process of the wiring board 100, the flexible core layer 130 can sustain the physical destruction caused by certain processes. For example, during the wiring jet-printing process, the flexible core layer 130 may absorb the pressure generated by the nozzle, so as to prevent the wiring board 100 from being broken during the manufacturing process. Therefore, through the flexible core layer 130, the situation that the wiring board 100 is broken may be reduced, so as to reduce the manufacturing cost of the wiring board 110, and to increase the yield of the wiring board 100.

In this embodiment, a thickness T1 of the wiring board 100 may be quite small, which may be between 30 μm and 150 μm. Although the thickness T1 of the wiring board 100 is between 30 μm and 150 μm, through the flexible core layer 130, the wiring board 100 may still have a good flexure between 0 degree and 175 degrees, and have a tensile strength between 20 Mpa and 150 Mpa. That is to say, even if the thickness T1 of the wiring board 100 is quite small, the wiring board 100 is more flexible and has a better flexibility than the conventional rigid wiring board.

The first wiring layer 110 and the second wiring layer 120 may be embedded in the flexible core layer 130, as shown in FIG. 1. That is to say, the wiring board 100 may be an embedded wiring board. Definitely, in other embodiments (not shown), the first wiring layer 110 and the second wiring 120 may be protruded from the flexible core layer 130. Therefore, the wiring board 100 shown in FIG. 1 is only intended for an exemplary illustration, but not to limit the present invention.

In addition, in other embodiments (not shown), the wiring board 100 may also include two solder mask layers, which may be solder mask adopted by the common rigid wiring board. The solder mask layers respectively cover the first wiring layer 110 and the second wiring layer 120, so as to protect the first wiring layer 110 and the second wiring layer 120. In addition, the solder mask layers partially expose the first wiring layer 110 and the second wiring layer 120, so as to enable the wiring board 100 to be assembled with the electronic components.

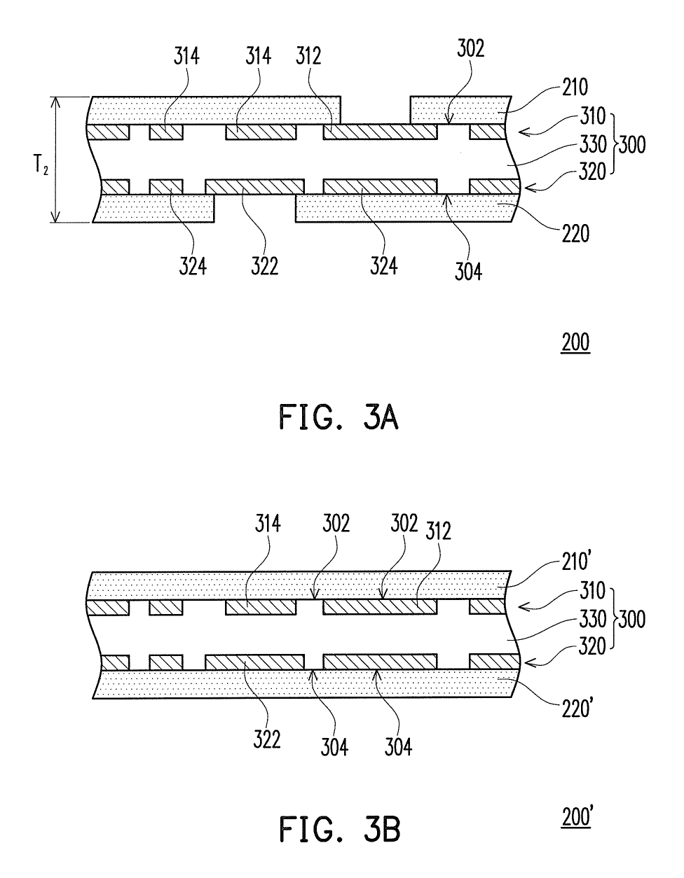

FIG. 3A is a schematic cross-sectional view of a wiring board according to another embodiment of the present invention. Referring to FIG. 3A, a wiring board 200 of this embodiment includes a first flexible insulating layer 210, a second flexible insulating layer 220, and a wiring substrate 300. The wiring substrate 300 has an upper surface 302 and a lower surface 304, in which the upper surface 302 is opposite to the lower surface 304. The first flexible insulating layer 210 is disposed on the upper surface 302, and the second flexible insulating layer 220 is disposed on the lower surface 304.

A flexure of the wiring board 200 is between 0 degree and 175 degrees, and a tensile strength of the wiring board 200 is between 20 Mpa and 150 Mpa. Therefore, as compared with the conventional rigid wiring board, the wiring board 200 is more flexible and has a better flexibility. In addition, in this embodiment, a thickness T2 of the wiring board 200 may be quite small, which is, for example, between 30 μm and 150 μm. Although the thickness T2 of the wiring board 200 is quite small, the flexure of the wiring board 200 is between 0 degree and 175 degrees, and the tensile strength thereof is between 20 Mpa and 150 Mpa, so the wiring board 200 is more flexible and has a better flexibility than the conventional rigid wiring board.

There are many means for enabling the flexure of the wiring board 200 to reach between 0 degree and 175 degrees. One of them is to utilize the first flexible insulating layer 210 and the second flexible insulating layer 220. Particularly, the first flexible insulating layer 210 and the second flexible insulating layer 220 with a high flexure or a high tensile strength may be adopted, for example, the first flexible insulating layer 210 and the second flexible insulating layer 220 with the flexure between 0 degree and 175 degrees or the tensile strength between 20 Mpa and 150 Mpa are selected.

The material of the first flexible insulating layer 210 and the second flexible insulating layer 220 may be selected from a solder mask, polyimide (PI), or liquid crystalline polymer (LCP) adopted by the common flexible wiring board, or any combination thereof. In this manner, through the first flexible insulating layer 210 and the second flexible insulating layer 220, the flexure of the wiring board 200 may be between 0 degree and 175 degrees, and the tensile strength of the wiring board 200 may be between 20 Mpa and 150 Mpa.

It should be noted that, in other embodiments (not shown), the wiring board 200 may only include one of the first flexible insulating layer 210 and the second flexible insulating layer 220, that is, the wiring board 200 includes the first flexible insulating layer 210 or the second flexible insulating layer 220. Therefore, the first flexible insulating layer 210 and the second flexible insulating layer 220 as shown in FIG. 3A are only intended to make an exemplary illustration, but not to limit the present invention.

The wiring substrate 300 may include a first wiring layer 310, a second wiring layer 320, and an insulating layer 330, in which the insulating layer 330 is disposed between the first wiring layer 310 and the second wiring layer 320. The insulating layer 330 may be formed by adopting a prepreg, or the insulating layer 330 may be made of the same material as the flexible core layer 130 as shown in FIG. 1.

The first flexible insulating layer 210 partially covers the first wiring layer 310, and the second flexible insulating layer 220 partially covers the second wiring layer 320. Particularly, the first wiring layer 310 includes at least one pad 312 and a plurality of wires 314, and the second wiring layer 320 includes at least one pad 322 and a plurality of wires 324.

The first flexible insulating layer 210 covers the wires 314, and exposes the pad 312, in which the first flexible insulating layer 210 may partially expose the pad 312 (as shown in FIG. 3A), or entirely expose the pad 312. The second flexible insulating layer 220 covers the wires 324, and exposes the pad 322, in which the second flexible insulating layer 220 may partially expose the pad 322 (as shown in FIG. 3A), or entirely expose the pad 322.

In addition, the wiring board 200 may be an embedded wiring board. That is to say, the first wiring layer 310 and the second wiring layer 320 may be embedded in the insulating layer 330, as shown in FIG. 3A. Definitely, in other embodiments (not shown), the first wiring layer 310 and the second wiring layer 320 may be protruded out of the insulating layer 330.

FIG. 3B is a schematic cross-sectional view of the wiring board in FIG. 3A during a manufacturing process. Referring to FIG. 3B, a wiring board 200′ as shown in FIG. 3B may be a semi-product obtained during the manufacturing process of the wiring board 200. The difference between the wiring board 200′ and the wiring board 200 lies in that, a first flexible insulating layer 210′ and a second flexible insulating layer 220′ entirely cover the upper surface 302 and the lower surface 304 of the wiring substrate 300 respectively.

Materials and physical properties (for example, flexure and tensile strength) of the first flexible insulating layer 210′ and the second flexible insulating layer 220′ are the same as that of the first flexible insulating layer 210 and the second flexible insulating layer 220. Therefore, during the manufacturing process of the wiring board 200, the first flexible insulating layer 210′ and the second flexible insulating layer 220′ enable the wiring board 200′ to have a better flexibility. In this manner, during the manufacturing process, the wiring board 200′ can sustain the physical destruction caused by certain processes.

For example, during the wiring jet-printing process, the first flexible insulating layer 210′ and the second flexible insulating layer 220′ may absorb the pressure generated by the nozzle, so as to prevent the wiring board 200′ from being broken during the manufacturing process. Therefore, through the first flexible insulating layer 210′ and the second flexible insulating layer 220′, the situation that the wiring board 200′ is broken may be reduced, so as to reduce the manufacturing cost, and to increase the yield of the wiring board 200.

Referring to FIGS. 3A and 3B, in this embodiment, a part of the first flexible insulating layer 210′ and a part of the second flexible insulating layer 220′ may be burnt through laser, so as to expose the pad 312 of the first wiring layer 310 and the pad 322 of the second wiring layer 320 (as shown in FIG. 3A), thereby forming the wiring board 200.

In addition, in other embodiments (not shown), it is also possible to remove the first flexible insulating layer 210′ and the second flexible insulating layer 220′ completely. Then, two solder mask layers are formed on the upper surface 302 and the lower surface 304 of the wiring substrate 300 respectively, in which the two solder mask layers may select the solder mask adopted by the common rigid wiring board or the common flexible wiring board.

The above manner for removing the first flexible insulating layer 210′ and the second flexible insulating layer 220′ completely may be peeling the first flexible insulating layer 210′ and the second flexible insulating layer 220′ in a manner of, for example, an irradiation peel or a heat peel.

To sum up, in the present invention, through the flexible core layer or the flexible insulating layers (for example, the first and second flexible insulating layers), the wiring board becomes relatively flexible, and the wiring board has a good flexibility. Therefore, as compared with the conventional rigid wiring board, the wiring board of the present invention may sustain the destruction of an external force.

In addition, the wiring board of the present invention is relatively flexible and has better flexibility, and thus, even if the thickness of the wiring board of the present invention is between 30 μm and 150 μm, the wiring board of the present invention can sustain larger destruction of the external force as compared with the conventional rigid wiring board. Therefore, the wiring board of the present invention has good product reliability.

Furthermore, the flexible core layer and the flexible insulating layers can further sustain the physical destruction caused by certain processes, such that the present invention can reduce the situation that the wiring board is broken during the manufacturing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wiring board, comprising:
a first wiring layer;
a second wiring layer; and
a flexible core layer, disposed between the first wiring layer and the second wiring layer, wherein the flexible core layer is an insulator, and a flexure of the wiring board is between 0 degree and 175 degrees.

2. The wiring board according to claim 1, wherein a tensile strength is between 20 Mpa and 150 Mpa.

3. The wiring board according to claim 1, wherein a tensile strength of the flexible core layer is between 20 Mpa and 150 Mpa.

4. The wiring board according to claim 1, wherein a thickness thereof is between 30 μm and 150 μm.

5. The wiring board according to claim 1, wherein the first wiring layer and the second wiring layer are embedded in the flexible core layer.

6. The wiring board according to claim 1, further comprising a first flexible insulating layer, disposed on the first wiring layer, wherein a flexure of the first flexible insulating layer is between 0 degree and 175 degrees.

7. The wiring board according to claim 6, wherein a tensile strength of the first flexible insulating layer is between 20 Mpa and 150 Mpa.

8. The wiring board according to claim 6, further comprising a second flexible insulating layer, disposed on the second wiring layer, wherein a flexure of the second flexible insulating layer is between 0 degree and 175 degrees.

9. The wiring board according to claim 8, wherein a tensile strength of the second flexible insulating layer is between 20 Mpa and 150 Mpa.

10. A wiring board, comprising:
a wiring substrate, comprising an upper surface and a lower surface opposite to the upper surface; and
a first flexible insulating layer, disposed on the upper surface, wherein a flexure of the wiring board is between 0 degree and 175 degrees.

11. The wiring board according to claim 10, wherein a tensile strength thereof is between 20 Mpa and 150 Mpa.

12. The wiring board according to claim 10, wherein a tensile strength of the first flexible insulating layer is between 20 Mpa and 150 Mpa.

13. The wiring board according to claim 10, wherein a thickness thereof is between 30 μm and 150 μm.

14. The wiring board according to claim 10, further comprising a second flexible insulating layer disposed on the lower surface, wherein a flexure of the wiring board is between 0 degrees and 175 degrees.

15. The wiring board according to claim 14, wherein a tensile strength of the second flexible insulating layer is between 20 Mpa and 150 Mpa.

16. The wiring board according to claim 10, wherein the wiring substrate comprises:
a first wiring layer;
a second wiring layer; and
an insulating layer, disposed between the first wiring layer and the second wiring layer, wherein the first flexible insulating layer partially covers the first wiring layer.
